(19) United States
(12) Patent Application Publication
(10) Pub. No.: US 2026/0132306 A1
(43) Pub. Date: May 14, 2026

(54) EXPANDABLE PROTECTIVE COATING

(71) Applicant: H. K. WENTWORTH LIMITED, Ashby de la Zouch Leicestershire (GB)

(72) Inventors: Christopher Allen, Swadlincote Leicestershire (GB); Phillip Kinner, Albert City Leicestershire (GB); Bethany Grace Turner, Sutton Coldfield West Midlands (GB)

(21) Appl. No.: 18/706,127

(22) PCT Filed: Dec. 2, 2022
(86) PCT No.: PCT/EP2022/084170

§ 371 Date: Apr. 30, 2024

(30) Foreign Application Priority Data
Dec. 3, 2021 (GB) 2117543.5

(51) Int. Cl. C09D 175/04; C08G 18/42; C08G 18/69; C08G 101/00; C08K 3/04; C08K 3/22; C09D 5/18; C09D 7/61; C09D 7/63

(52) U.S. Cl. CPC C09D 175/04; C08G 18/4241; C08G 18/4277; C08G 18/69; C08K 3/04; C08K 3/22; C09D 5/18; C09D 7/61; C09D 7/63; C08G 2101/00; C08G 2110/0083; C08G 2150/90; C08K 2003/2227

(57) ABSTRACT

The present disclosure is directed to a two-part coating composition, wherein the two-part coating composition comprises: Part A comprising (a) a polyol component comprising at least one of a difunctional polyol, a trifunctional polyol, and a tetra functional polyol; (b) a foam catalyst; (c) optionally, a gel catalyst; and (d) water; and Part B comprising an isocyanate functional material, wherein the isocyanate functionality is at least 2, preferably an isocyanate prepolymer with a functionality of greater than 2 and less than 3. The coating composition produced an expanded closed-cell foam coating that provides protection for electronic substrates operating in harsh environments.

### FIELD OF THE INVENTION

The present disclosure generally relates to an expandable protective coating material and a method of coating one or more surfaces of a substrate using the expandable protective coating material.

### BACKGROUND OF THE INVENTION

Protective coatings are used in various applications to provide resistance to thermal shock, high temperature, and relative humidity and to protect against condensation and immersion. In many applications, it is desirable that surfaces of a substrate, including surfaces that contain one or more features, be protected against the environment and from damage. These substrates includes electronic assemblies for which protection and/or encapsulation of features contained thereon is desired.

Electrical circuits are typically mounted on support substrates such as printed circuit boards (PCBs) and printed wiring boards (PWBs) having suitable electrical characteristics including dielectric strength, power factor, insulating characteristics, etc. The support substrate also exhibits the necessary physical properties for a given application, including tensile strength and tear resistance.

Environmental usage is also be considered in the design, construction and manufacture of electrical circuit systems. The humidity and/or temperature of the environment within which the electrical circuit operates may have substantial significance on the design. In many environments, the circuit specification requires a protective enclosure and both electrical and physical characteristics of the enclosure are considered in relationship to the environmental conditions to be encountered, including possible extreme variations in conditions.

Common protective coatings for electronic assemblies include, but are not limited to, potting materials, other encapsulation resins, and conformal coatings.

One of the main objectives of potting materials is to provide protection and support of sensitive electronics in environments including exposure to chemical, high humidity, vibration, and temperature extremes. While these potting materials are successful, they are often very heavy. That is, potting materials that are used to fill the device or assembly are often very thick, which can be disadvantageous for certain applications. Potted objects are also not easily re-enterable (i.e., soft enough to cut into for ease of removal for inspection and/or repair of the filled component). One example of a potting material for filling an electronic device or assembly is described in U.S. Pat. No. 8,614,266 to Li et al., the subject matter of which is herein incorporated by reference in its entirety.

By encapsulating the entire surface of the electronic substrate, encapsulation resins provide complete insulation for the unit, combining good electrical properties with mechanical protection. These resins are generally two-component systems, in which a resin (Part A) is mixed with the correct amount of hardener (Part B), to start a chemical reaction leading to a cross-linked polymer. Encapsulations resins are described, for example, in U.S. Pat. Pub. No. 2016/0322283 to McMahon et al., the subject matter of which is herein incorporated by reference in its entirety.

Potting materials and encapsulating resins offer a high level of protecting for electronic substrates such as printed circuit boards (PCBs). These resins can be applied from a thickness of about 0.5 mm and up and are generally much thicker. The increased thickness leads to a significant increase in weight. On the other hand, the increased thickness provides far greater protection against chemical attack, especially in the case of prolonged immersion. In addition, the resin can provide superior protection against physical shock since the bulk of the resin can help to dissipate the forces across the electronic substrate. Use of dark colored resins can also complete hide the PCB, which can allow for some security of the design. However, these resins can also be difficult to remove, making rework of the PCB impractical as the removal may result in the destruction of the PCB.

On the other hand, conformal coatings are typically applied as a very thin coating to provide the maximum level of protection possible while using the thinnest amount of material to minimize heat entrapment and additional weight. Conformal coatings may be applied, for example, at a thickness of about 25-250 micron dry film thickness range, leading to a minimal weight increase of the assembly. Conformal coatings protect the electronic substrate (e.g., PCB) and its components from the environment and from corrosion. Because the material is applied to the board after it is assembled, it “conforms” to the shape of the board and its components. Conformal coatings can cover the entire circuit board (if desired) and protect both the board and its parts including the component leads, solder joints, exposed traces, and other areas of exposed metal. The thin coating protects the metal from corrosion as well as providing shielding of the entire board from spray, moisture, fungus, dust, and other contaminations from harsh environments. Conformal coatings can also help prevent damage from thermal and mechanical stress and even rough handling helping to extend the operational life of the PCB.

Conformal coatings are typically non-conductive dielectric materials and can increase the dielectric strength between traces and other metal conductors, reducing the surface area required for circuitry, which allows for more compact and dense PCB layouts. There are different types of conformal coating materials or chemistries that are used depending on the specific needs of the electronic substrate. Some of the more commonly used conformal coatings include acrylic resins, silicone resins, urethane resins, and epoxy resins. Examples of conformal coatings can be found in U.S. Pat. No. 4,300,184 to Colla, the subject matter of which is herein incorporated by reference in its entirety, which describes a moisture-free coating material that contains a fumed silica powder and a single-component urethane coating formulation and is process to remove all air bubbles from the formulation. WO03/013199 to Glatkowski et al. describes a conformal coating that provides shielding against electromagnetic interference and contains carbon nanotubes.

The majority of conformal coatings are single component systems, which have a long useable life, a low curing or drying temperature and short drying time. Being a single-part solution, they are clearly easier to process and apply; however, the majority of single component coatings are solvent-based to modify their viscosity for application purposes. Conformal coatings can be applied manually by various meanings, including brushing, spraying and dipping.

Two-part polyurethane coatings can also be used which combine the protection and properties of a resin with the ease of application of a conformal coating, but without the use of solvents, which provides an environmental advantage. These coatings can provide excellent coverage and their flexibility offers protection of delicate components. Two-component coatings deliver excellent mechanical properties and abrasion resistance but being two-part, require more involved application equipment than one-component coatings. These two-component coatings can also be more difficult to remove, making board repair very difficult.

A critical problem with conformal coatings is the difficulty in effectively covering interconnecting projecting pin-like circuit elements on the PCB or PWB, as these elements may remain at least partially exposed with the use of conformal coatings. In such instances, a potting material may be required in addition to the conformal coating to embed the circuit and completely encapsulate minute protrusions and asperities, which adds significant weight.

In an effort to fill the gap between thick encapsulation resins and potting materials and thin dielectric conformal coatings, low hardness, low modulus formulated resin systems have been suggested. These resins are designed to provide mechanical structural support while providing vibrational dampening and reducing the overall resin weight and cost. Examples of these coatings can be found in U.S. Pat. Nos. 9,832,902 and 9,699,917, both to Jordan, Jr. et al., the subject matter of each of which is herein incorporated by reference in its entirety. However, these coatings still suffer from the same difficulties of inadequate coverage of features.

As seen in FIG. 1, a typical conformal coating has difficulties in completely covering features on the electronic substrate and edges of such features may be left uncovered, leading to incomplete protection. On the other hand, as shown in FIG. 2, potting materials are very dense materials that provide protection of the features but add to the weight of the final product.

As an alternative to conformal coatings and encapsulation and potting resins, electronic substrates may be partially covered with an epoxy resin or microencapsulated. However, these methods are typically only used in certain areas or to cover selected components.

Thus, it can be seen that there remains a need for an improved protective coating that can provide superior protection of one or more surfaces of a substate, especially substrates that include projecting circuit elements and other projecting features that can be difficult to completely cover or coat.

Various two-part foam compositions have been developed that exhibit desirable properties.

GB1496922 describes a foam composition comprising a polyol A, a polyisocyanate M (a blend of TDI and polymeric isocyanate), water, and Catalysts N (triethylenediamine in dipropylene glycol), P (bis(2-dimethylamine ether)ether), R (amine catalyst), and S (dibutyl tin dilaurate).

US20130225706 describes a foam composition in which a first part comprises trifunctional polyols, a chain extender, water, amine catalysts in dipropylene glycol, and a tin catalyst. A second part is comprised of polymeric MDI.

US20090247659 describes a two-component foam composition comprising Part A and Part B and in which Part A is comprised of polymeric MDI and Part B comprises an aromatic polyester polyol, an oxypropylated polyether triol, a tertiary amine catalyst, potassium octoate catalyst, and water.

CN112552474 describes a two-part foam composition in which a first part comprises a glycerin-based polyether polyol, a propylene glycol-based polyether polymer, an amine catalyst (N,N-dimethylcyclohexylamine), a tin catalyst (dibutyltin dilaurate), and water and a second part comprises polymethylene polyphenyl polyisocyanate.

CN106750095 describes a two component composition comprising a glycine-based polyol, a triethylenediamine catalyst, a dibutyl tin laurate catalyst, and polymeric MDI. The isocyanate is kept separate from a mixture containing the other ingredients and the two are combined when in use.

New coatings formulations that are lightweight and that provide complete coverage and/or encapsulation of the circuit elements and other features are highly desired.

### SUMMARY OF THE INVENTION

It is an object of the present invention to provide an improved protective coating composition.

It is another object of the present invention to provide a protective coating composition that provides superior coating of features mounted on an electronic substrate.

It is another object of the present invention to provide a method of coating or encapsulating features on an electronic substrate.

It is another object of the present invention to provide a coating composition that produces a protective coating that is low stress.

It is another object of the present invention to provide a protective coating that provides a weight savings as compared with coatings of the prior art.

It is another object of the present invention to provide a coating that is electrically insulating.

It is another object of the present invention to provide a coating that it resistant to thermal shock, high temperature, and relative humidity.

It is still another object of the present invention to provide a coating that protects against condensation and immersion.

It is still another object of the present invention to provide a coating that provides flame retardancy.

It is still another object of the present invention to provide a coating that is aesthetically pleasing.

It is still another object of the present invention to provide a coating that can be coupled to a topcoat layer to provide additional protection.

It is still another object of the present invention to provide a coating that has low viscosity.

To that end, in one aspect, the present invention relates generally to a two-part protective coating composition, wherein the two-part protective coating composition comprises:
a) Part A comprising:
   a. a polyol component comprising at least one of a difunctional polyol and a trifunctional polyol;
   b. a foam catalyst;
   c. optionally, a gel catalyst;
   d. optionally, at least one flame retardant; and
   e. water; and
b) Part B comprising:
   an isocyanate functional material, wherein the isocyanate functionality is at least 2, preferably wherein the isocyanate functional material is an isocyanate prepolymer, wherein the isocyanate prepolymer has a functionality of greater than 2 and less than 3, and
   optionally, at least flame retardant;
wherein the flame retardant must be present in at least one of Part A and Part B.

The two-part protective coating composition described herein can be mixed to produce a lightweight, closed-cell foam protective coating that can be applied to one or more surfaces of a substrate to protect the surfaces from the environment, chemical attack and moisture, thermal shock, etc. and to provide flame retardancy.

In a second aspect, the present invention relates generally to a method of applying a protective coating to one or more surfaces of a substrate, the method comprising the steps of:
a) mixing a two-part coating composition comprising:
   i) Part A comprising:
      a. a polyol component comprising at least one of a difunctional polyol, a trifunctional polyol, and a tetra functional polyol;
      b. a foam catalyst;
      c. optionally, a gel catalyst;
      d. optionally, at least one flame retardant; and
      e. water; and
   ii) Part B comprising:
      an isocyanate functional material, wherein the isocyanate functionality is at least 2, preferably wherein the isocyanate functional material is an isocyanate prepolymer with a functionality of greater than 2 and less than 3, and
      optionally, at least one flame retardant,
      wherein the at least one flame retardant must be present in at least one of Part A and Part B, to prepare a liquid coating composition; and
b) applying the liquid coating composition to a substrate and allowing the liquid coating composition to expand into a closed-cell foam coating

In a third aspect, the present invention relates generally to an electronic substrate assembly comprising a printed circuit board, wherein the printed circuit board comprises a base support and a plurality of electrical circuit components extending outwardly from the surface of the base support attached thereto and electrically connected to the electrical circuitry, and wherein a closed-cell foam protective coating is applied to at least a portion of the surface of the electronic substrate assembly comprising the plurality of electrical circuit components, wherein the closed-cell protective coating comprises the two-part coating composition of the first aspect of the present invention, wherein Parts A and B are in a mixed form in the closed-cell protective coating, and/or the closed-cell protective coating is applied by the method of the second aspect of the present invention.

Additional advantageous features, functions and applications of the disclosed systems and methods of the present disclosure will be apparent from the description which follows, particularly when read in conjunction with the appended figures.

### BRIEF DESCRIPTION OF THE DRAWINGS

Features and aspects of embodiments are described below with reference to the accompanying drawings, in which elements are not necessarily depicted to scale, and in certain views, parts may have been exaggerated or removed for purposes of clarity.

Exemplary embodiments of the present disclosure are further described with reference to the appended figures. It is to be noted that the various features, steps and combinations of features/steps described below and illustrated in the figures can be arranged and organized differently to result in embodiments which are still within the scope of the present disclosure.

The present invention will now be described with reference to the following figures, in which:

FIG. 1 depicts a cross-sectional view of a prior art conformal coating on features of an electronic substrate.

FIG. 2 depicts a view of an electronic substrate in which the features are coated with a prior art resin potting material.

FIG. 3 depicts a view of three different electronic assemblies that have been coated with the expanded protective coating of the present invention.

FIG. 4 depicts the results of the Surface Insulation Resistance measurements of the composition of Example 1.

FIG. 5 depicts a view of an electronic assembly coated with the expanded protective coating of the invention and in which the coating is exposed to thermal shock testing.

FIG. 6 depicts the results of the Surface Insulation Resistance measurements of the composition of Comparative Example 1.

FIG. 7 depicts a view of an electronic assembly that has been partially coated with the protective coating of the invention.

FIG. 8 depicts a view of the electronic assembly of FIG. 7 that has been further coated with a top coat over the top of the protective coating layer.

FIG. 9 depicts a comparison of an electronic assembly coated with the composition of Example 1 and an electronic assembly coated with the composition of Comparative Example 1 after 1000 hours at 85° C./85% RH.

FIG. 10 depicts a graph that demonstrates the weight savings of the coating composition of the invention as compared with a prior art encapsulating coating.

FIG. 11 depicts a view of a substrate coated with the foam coating of the invention, with and without a top coat layer.

FIG. 12 depicts a graph that shows the improvement in water-uptake achieved by over-coating the foam with a top coat layer.

FIG. 13 depicts a graph of the electrical insulation of a coating in accordance with the instant invention under immersion at 50° C. for 1 week.

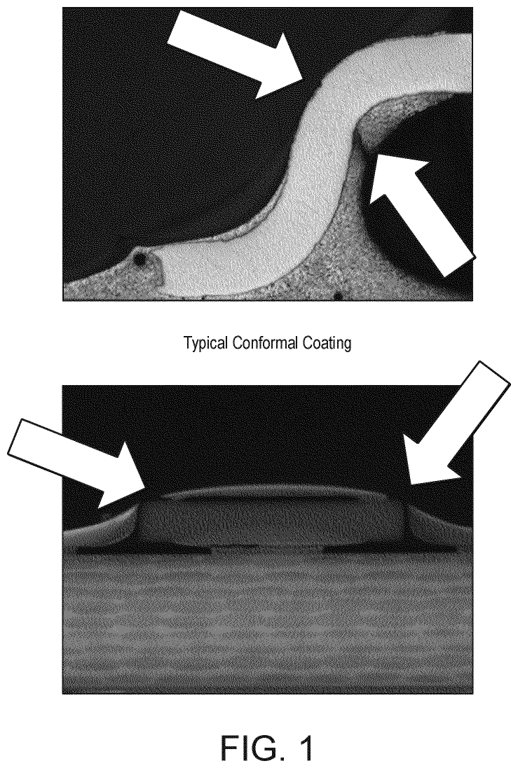

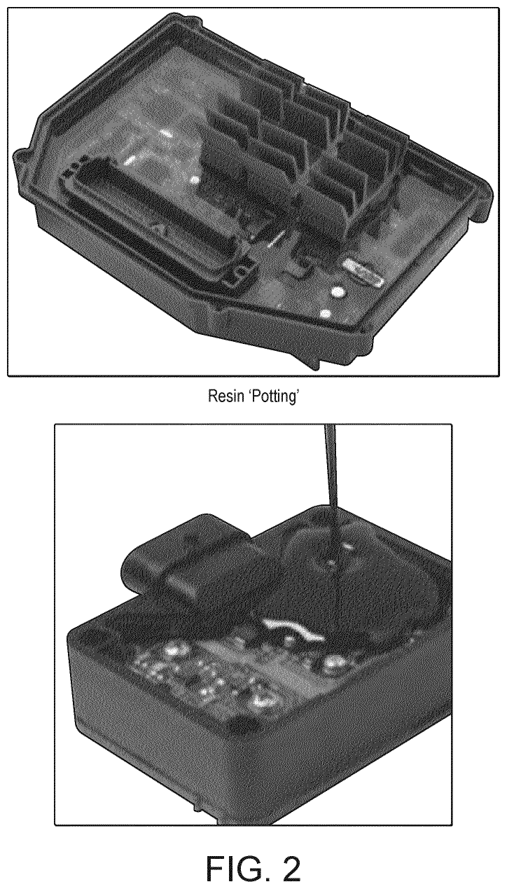

Also, while not all elements may be labeled in each figure, all elements with the same reference number indicate similar or identical parts.

### DETAILED DESCRIPTION OF THE INVENTION

The present invention relates generally to an expandable liquid coating composition that possesses certain performance characteristics for producing an expanded protective coating that is capable of coating and/or encapsulating features of a substrate, including electronic substrates that include minute protrusions and asperities. The electronic substrate may be a surface mount electronic device containing one or more circuit elements. In addition, the protective coating may be designed to protect the electronic substate from harsh environments, including exposure to chemical, high humidity, vibration, and temperature extremes for prolonged periods of time.

The protective coating may also be designed to provide improved flame retardancy.

The present invention provides a liquid applied, elastic coating composition that expands to a closed-cell foam coating and can be used to provide a protective coating for electronic assemblies and other substrates. In addition, the coating composition can be used in a process of repairing or modifying an electronic substrate such as a PCB or PCW, as the repaired or modified circuit board can be easily overcoated using the coating composition and processes detailed herein.

The present invention thus provides an expandable protective coating which can be applied to printed circuit systems and other electronic such substates, including substrates that include small asperities and projections requiring protection. The expandable coating composition is applied as a liquid and quickly expands to form an expanded closed-cell foam protective coating.

It should be understood that the disclosed embodiments are merely illustrative of the present disclosure, which may be embodied in various forms. Therefore, details disclosed herein with reference to exemplary assemblies/fabrication methods and associated processes/techniques of assembly and use are not to be interpreted as limiting, but merely as the basis for teaching one skilled in the art how to make and use the advantageous assemblies/systems described herein.

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath”, “below”, “lower”, “above”, “upper”, “front”, “back”, and the like, are used for ease of description to describe one element or feature's relationship to another element(s) or feature(s). It is further understood that the terms “front” and “back” are not intended to be limiting and are intended to be interchangeable where appropriate.

As used herein, the terms “comprise(s)” and/or “comprising,” specify the presence of stated features, integers, steps, operations, elements, and/or components, but do not preclude the presence or addition of one or more other features, integers, steps, operations, elements, components, and/or groups thereof.

Where reference is made to an ASTM or other standard herein, the standard is expected to be the latest standard as of the filing of the application if not otherwise defined.

As used herein, the term “polyol” refers to an organic compound that contains multiple hydroxyl groups.

In one aspect, the present invention relates generally to a two-part coating composition, wherein the two-part coating composition comprises:
a) Part A comprising:
   a. a polyol component comprising at least one of a difunctional polyol, a trifunctional polyol, and a tetra functional polyol;
   b. a foam catalyst;
   c. optionally, a gel catalyst;
   d. optionally, one or more additives selected from the group consisting of foam stabilizers, copolymers, inert mineral fillers or extenders, colorants, antioxidants, UV-stabilizers, and flame retardants, and
   e. water; and
b) Part B comprising:
   an isocyanate functional material, wherein the isocyanate functionality is at least 2, preferably an isocyanate prepolymer with a functionality of greater than 2 and less than 3.

In one aspect, the present invention relates generally to a two-part coating composition, wherein the two-part coating composition comprises:
c) Part A comprising:
   a. a polyol component comprising at least one of a difunctional polyol, a trifunctional polyol, and a tetra functional polyol;
   b. a foam catalyst;
   c. optionally, a gel catalyst;
   d. optionally, at least one flame retardant, and
   e. water; and
d) Part B comprising:
   an isocyanate functional material, wherein the isocyanate functionality is at least 2, preferably an isocyanate prepolymer with a functionality of greater than 2 and less than 3 and
   optionally, at least one flame retardant;
   wherein the at least one flame retardant must be present in at least one of Part A and Part B.

The polyol component of Part A includes at least one of a difunctional polyol, a trifunctional polyol, and a tetra functional polyol and may include an additional polyol that is capable of reacting with an isocyanate group. Examples of such polyols include glycols, i.e., diols containing a 1,2 dihydroxy group such as ethylene glycol or propylene glycol and derivatives thereof, polypropylene glycol, polytetramethylene ether glycol, and glycerol or glycerin and derivatives thereof. In one embodiment, the polyol(s) of the polyol component have a molecular weight of less than about 2,000, more preferably less than about 1,000, more preferably less than about 600, more preferably a weight average molecular weight from about 300 to about 600 Daltons.

In some embodiments, the polyol is an asymmetric diol having from 3 to 20 carbon atoms, more preferably 4 to 12 carbon atoms, and most preferably 5 to 10 carbon atoms. Examples of such asymmetric diols include, but are not limited to, 2-ethyl-1,3-hexanediol, 1,2-propanediol, 1,3-butanediol, 2,2,4-trimethyl-1,3-pentanediol, 1,12-octadecanediol, 1,2-hexanediol, 1,2-octanediol, and 1,2-decanediol. Other examples of polyols include a tetrol such as pentaerythritol. The polyol can also be a polyether polyol prepared from either ethylene oxide and/or propylene oxide optionally reacted with another polyol such as glycol or glycerol.

Suitable polyols include polyether polyols, polyester polyols, polymer polyols which comprise a dispersion of polymer particles in a continuous polyol phase, and other polyhydroxy containing compounds. Preferred polyols include poly(tetramethylene oxide) polymers, copolymers of tetramethylene oxide and ethylene oxide and polymers and copolymers of propylene oxide, by way of example and not limitation.

In one embodiment, the polyol component comprises at least one of a difunctional polyol, a trifunctional polyol, and a tetra functional polyol. In one embodiment, the polyol component comprises more than one of a difunctional polyol, a trifunctional polyol, and a tetra functional polyol.

In one embodiment, the difunctional polyol is selected from the group consisting of polyethylene glycol, polypropylene glycol, polycaprolactone, polybutadiene, polyester, polyether, polyfarnesene, ethylene glycol dimerates, and combinations of two or more of the foregoing. Preferably, the difunctional polyol is a hydrophobic polyol selected from the group consisting of polybutadiene, polyfarnesene, and ethylene glycol dimerates.

In one embodiment, the trifunctional polyol is selected from the group consisting of polyethylene glycol, polypropylene glycol, polycaprolactone, polybutadiene, polyester, polyether, polyfarnesene, ethylene glycol dimerates, and combinations of two or more of the foregoing. In one embodiment, the trifunctional polyol comprises castor oil (i.e., ricinoleic acid triglyceride), which is a renewable raw material that is widely commercially available.

Derivatives of castor oil, including any polyol derived from castor oil, which includes a hydrolysis product, an ethoxylated product, a transesterfied product, or an esterfied product, or a polyamide product can also be used in the practice of the instant invention. Another example of a suitable trifunctional polyol is a cashew nut liquid (CNSL) based polyol.

In one embodiment, the polyol component comprises 0 to 99.99 wt. %, more preferably 0.1 to 99.9 wt. %, preferably 30-70 wt. %, more preferably 45-55 wt. % of the difunctional polyol and/or 0.0 to 99.99 wt. %, more preferably 0.1 to 99.9 wt. %, preferably 30-70 wt. %, more preferably 45-55 wt. % of the trifunctional polyol, and/or 0.0 to 99.99 wt. %, more preferably 0.1 to 99.9 wt. %, preferably 30-70 wt. %, more preferably 45-55 wt. % of the tetra functional polyol.

In one embodiment, the water content of Part A is in a range of 0.05 to 10 wt. %, more preferably 0.1 to 9 wt. %, more preferably 0.5 to 8 wt. %, or optionally in the range of 3 to 7 wt. %, or optionally in the range of 4.5 to 5.5 wt. %.

Part A also comprises one or more catalysts. In one embodiment, the catalyst comprises a blend of foam catalysts along with gel catalysts to control the kinetics of the gel and blow reaction. In another embodiment, the catalyst comprises one or more foam catalysts. In another embodiment, a single catalyst is used as both the foam and gel catalyst.

The blow/foam catalyst preferentially catalyzes the reaction between the water and isocyanate source to produce carbon dioxide. In one embodiment, the foam catalyst comprises, for example, triol catalysts, tetra polyol catalysts, and amine catalysts, including tertiary amine catalysts. Further examples of suitable catalysts include various alkyl amines, aliphatic amines, aromatic amines, alkyl ethers, and alkyl thiol ethers, such as those of bismuth or tin, including bismuth octoate, bismuth laurate and other similar compounds. Other catalysts include tine catalysts such as stannous octoate, dibutyltin dioctoate, and dibutyltin dilaurate.

Suitable amine catalysts include, but are not limited to fatty amines, alicyclic amines, aromatic amines, alcohol amines or one of their ammonium compounds. Examples of aliphatic amines include, but are not limited to triethylenediamine, N,N,N,N-tetramethylalkylenediamine, N,N,N,N-pentamethyldiethylenetriamine, triethylamine, N,N-dimethylbenzylamine, N,N-dimethylhexadecylamine, N,N-dimethylbutylamine, among others. Examples of alicyclic amines include, but are not limited to, triethylenediamine, N-ethylmorpholine, N-methylmorpholine, N,N-diethylpiperazine, N-diethyl-2-methyl piperazine, N,N-bis-(α-hydroxypropyl)-2-methylpiperazine, N-hydroxypropyldimethylmorpholine, among others.

Examples of aromatic amines include pyridine, N,N-dimethylpyridine, among others.

Commercial amine catalysts usable in compositions described herein include bis(2-dimethylaminoethyl) ether (available from Momentive Performance Materials under the tradename NIAX A-1), triethylenediamine dipropylene glycol solution (available from Momentive Performance Materials under the tradename NIAX A-33), tertiary gel amines (available from Momentive Performance Materials under the tradename NIAX Catalyst EF-600), and tertiary amines (Available from Momentive Performance Materials under the tradename NIAX Catalyst EF-700). Other similar amine catalysts would also be known to those skilled in the art and usable in the composition of the present invention.

The amine catalyst is used in the composition in a suitable amount to control the reaction during synthesis of the polyurethane foam. In one embodiment, the amine catalyst is used in an amount of between about 0.01 and about 5 wt. % of Part A, preferably about 0.5 to about 2.5 wt. %, more preferably about 0.75 to about 1.25 wt. % of Part A.

The gel catalyst promotes the gelling reaction to trap the produced carbon dioxide in a polymer matrix to yield the close-cell foam protective coating. In one embodiment, the gel catalyst comprises an organo-metallic catalyst which may be, for example a tin, bismuth, or potassium based catalyst. Examples of these organo-metallic catalysts include, for example tin catalysts such as dialkyl tin dialkanoates, stannous octoate, dibutyltin dilaurate, dibutyltin diacetate, a blend of zinc neodecanoate, bismuth neodecanoate and neodecanoic acid, ferric acetylacetonate, potassium acetate catalysts, potassium octoate catalysts, stannous octoate catalysts, and bismuth based gelation catalysts, by way of example and not limitation. One example of a commercial organo-tin catalyst is available from EVONIK under the tradename Kosmos 16. In another embodiment, the gel catalyst is a gel amine catalyst such as NIAX A33 or NIAX EF600, available from Momentive Performance Materials Inc.

In one embodiment, the gel catalyst is used in an amount of between about 0.01 and about 5 wt. % of Part A, preferably about 0.05 to about 0.5 wt. %, more preferably about 0.1 to about 0.3 wt. % of Part A.

The total amount of catalyst in Part A (i.e., total “polyol-side” composition) may vary depending in part depend on the method of applying the expandable coating composition. For example, in spray coating applications, the total amount of catalyst present may optionally, but preferably, be in the range of greater than zero percent to less than 1 wt. % of the total “polyol-side” composition, including a gel catalyst level of between 0.2 percent and 0.8 percent of the total “polyol-side” composition and a blow catalyst levels of between 0.2 percent and 0.8 percent of the total “polyol-side” composition. On the other hand, for dispensing operations, preferred gel catalyst levels are between 0.02 percent and 0.25 percent of the total “polyol-side” and preferred blow catalyst levels are between 0.02 percent and 0.25 percent of the total “polyol-side” composition.

As discussed above, Part B of the coating composition comprises an isocyanate functional material, wherein the isocyanate functionality is at least 2. In one embodiment, the isocyanate functional material comprises an isocyanate prepolymer with an average functionality of greater than 2 and less than 3.

In one embodiment, the isocyanate prepolymer is the reaction product between diphenylmethane 4,4′diisocyanate ad/or diphenylmethane 2,2′-diisocyanate, and or diphenylmethane 2,4′-diisocyanate (MDI) and a polyester polyol based on adipic acid, 2-methyl-1,3-propanediol and trimethylolpropane.

In one embodiment, polyisocyanates used to prepare the prepolymer of the polyurethane composition include any compounds having at least two isocyanate moieties, including diisocyanates such as 1,5-naphthylene diisocyanate, 4,4′-diphenylmethane diisocyanate (4,4′-MDI), 4,4′-diphenyldimethylmethane diisocyanate, 4,4′-dibenzyl diisocyanate, dialkyldiphenylmethane diisocyanate, 1,3-phenylene diisocyanate, 1,4-phenylene diisocyanate, toluene diisocyanate, butane-1,4-diisocyanate, hexamethylene diisocyanate, isopropylene diisocyanate, naphthylene diisocyanate, methylene diisocyanate, 2,2,4-trimethylhexamethylene diisocyanate, cyclohexane-1,4-diisocyanate, xylylene diisocyanate, hydrogenated xylylene diisocyanate, isophorone diisocyanate, lysine diisocyanate, dicyclohexylmethane-4,4′-diisocyanate, 1,3-bis(isocyanatomethyl)cyclohexane, methyl-cyclohexane diisocyanate, m-tetramethylxylylene diisocyanate, 2,4,6-triisopropylbenzene diisocyanate, isopropylidene bis(4-cyclohexylisocyanate), and mixtures thereof. Preferred mixtures of diisocyanates include mixtures of 4,4′-MDI and 2,4-MDI.

The polyisocyanate used to prepare the prepolymer can also be a polyisocyanate prepared, for example, by reacting a diisocyanate with a diisocyanate-reactive compound such as a polyol e.g., a diol or polyamine, e.g., a diamine. Exemplary polyisocyanates used to prepare the prepolymer include polymeric forms of MDI. The polyisocyanate used to prepare the prepolymer can also be a carbodimide-modified diisocyanate, e.g., a carbodiimide-modified MDI.

As discussed above, the polyisocyanate generally has an average functionality between about 2 and about 3, more preferably between 2.1 and 3, more preferably between 2.1 and 2.9, more preferably between 2.3 and 2.8, most preferably between 2.5 and 2.7.

In one embodiment, the isocyanate prepolymer comprises an MDI trimer such as a solvent-free product based on 4,4′-diphenylmethane diisocyanate (MDI) having an average functionality of 2.7, a commercial product of which is available from BASF under the tradename Lupranat® M20S. In this embodiment, what is important is that the isocyanate prepolymer react sufficiently quickly with water and the polyol component. By “sufficiently quickly” what is meant is that the isocyanate prepolymer reacts with water and the polyol component in less than 10 minutes, preferably less than 8 minutes, preferably less than 7 minutes, preferably less than 6 minutes, preferably less than 5 minutes, preferably less than 4 minutes, and most preferably less than 3 minutes to produce the expanded closed-cell foam protective coating. The balance of carbon dioxide generation and polymerization is important and must be complimentary. The polymerization must proceed quickly to trap carbon dioxide as it is being generated. If the carbon dioxide generation is faster than the polymerization, the foam will collapse. In a preferred embodiment, once carbon dioxide generation begins, the polymerization must also begin.

In another embodiment, the formulation is optimized for a delayed reaction.

In one embodiment, a chain extender may also be included in Part A of the composition to provide tailoring properties. The chain extender is typically a low molecular weight diol or diamine that reacts with diisocyanates to build polyurethane molecular weight and increase the block length of the hard segment. Examples of suitable low molecular weight chain extenders include aliphatic, araliphatic, aromatic and/or cycloaliphatic compounds, more preferably a bifunctional compound such as a diamine and/or alkane diol having from 2 to 10 carbon atoms in the alkylene radical, such as 1,2-ethylene diol, 1,4-butanediol, 1,6-hexanediol, 1,3-propanediol, and/or dialkylene-, trialkylene-, tetraalkylene-, pentaalkylene-, hexaalkylene-, heptaalkylene-, octaalkylene-, nonalkylene, and/or decaalkylene-glycols having from 2 to 8 carbon atoms in the alkylene moiety, corresponding oligopropyleneglycols and/or propylene glycols. Other examples of suitable chain extenders include, but are not limited to, 1,4-butanediamine, ethylene diamine, diaminopropane, cyclohexane diphenylalanine, among others. Combinations of two or more of the foregoing can also be used. The concentration of the chain extender in Part A, if used, may be within the range of about 2 to about 20 wt. %, more preferably about 5 to 15 wt. %.

In one embodiment, the protective coating composition comprises a flame retardant. If used, the flame retardant may comprise, for example, aluminum hydroxide trihydrate (ATH), phosphorus containing polyol, or micro-encapsulated ammonium poly phosphate. Alternatively or in addition, the flame retardant may also include a component that is a solid at room temperature. Suitable flame retardant materials that are a solid at room temperature have a typical average particle size of 50 to 500 microns, more preferably 100 to 400 microns, more preferably 90 to 350 microns. In one embodiment, the solid flame retardant component is made from expandable graphite flakes, a commercial product of which is available under the tradename GrafGuard (from NEOGRAF Solutions, Ohio, USA). In one embodiment, the flame retardant comprises ATH and expandable graphite flakes.

The solid flame retardant component may be present in at least one of the reactive components (i.e., either Part A or Part B). In one embodiment, the solid flame retardant component is present in at least one of the reactive components at a weight percent from greater than zero percent to less than 70 percent, based on the total weight of the component. In some embodiments, the flame retardant component may be present in both the first component (Part A) and the second component (Part B). Moreover, the solid flame retardant component may be present in the cured protective coating composition in a weight percent of between 5 percent and 50 percent, more preferably about 10 percent to about 40 percent or about 20 percent to about 35 percent or about 25 percent to about 30 percent based on the total weight of cured composition.

In one embodiment, in which the two-part coating composition is formulated for spray applications, the solid flame retardant has a particle size in the range of 80 to 100 microns, more preferably in the range of about 85 to about 95 microns. In one embodiment, in which the two-part coating composition is formulated for dispensing applications, the solid flame retardant has a particle size in the range of about 60 to about 180 microns, preferably about 70 to 160 microns, more about 90 to about 150 microns. The flame retardant may be added to Part A of the composition at a concentration in the range of about 10 to about 30 wt. %, more preferably about 15 to about 20 wt. %.

The benefits of using expandable graphite in the expandable compositions described herein is that the formulation contains no halogenated materials. In addition, the use of expandable graphite as the flame retardant also does not negatively impact electrical properties unlike phosphorus-based polyols that are known to be susceptible to hydrolysis and give unacceptable electrical performance in high temperature/humidity environments. In addition, compositions containing expandable graphite also meet UL94 V-0 requirements at low loading. In one embodiment, the expandable graphite is present in the composition at a concentration in the range of 5-30 wt. %, more preferably 10-20 wt. %, which is a concentration that is sufficient to pass UV94 V-0 testing at a foam density of 0.2 g/cm³. Thus, compositions containing a fire retardant such as expandable graphite, were capable of passing UL94 V-0 testing without significantly impacting the density of the foam or negatively affecting the electrical insulation properties of the foam. Also, low density foams are still achievable as compared with compositions that use ATH as the flame retardant. Some grades also impart desirable thixotropic rheology.

The protective coating composition of the invention may also optionally, but preferably, include an inert mineral filler or extender, such as talc, calcium carbonate, silica, wollastonite, aluminum hydroxide, clays such as kaolins, calcium sulfate fibers, mica, glass beads, and nanomaterials, such as nano-graphene, nanofibers and nanoparticles. Other inert mineral fillers would also be known to those skilled in the art.

The protective coating composition may also optionally, but preferably, include a colorants such as a dye, or pigment to provide a specific color to the coating material. These colorants are selected to avoid any chemical incompatibility between the chemistry of the protective coating composition and the chemistry of the colorant and are used in an amount to provide a desired color of the resulting expanded closed-foam protective coating.

The protective coating composition may also optionally, but preferably, include an anti-oxidant or UV-stabilizing material. Examples of these materials include, but are not limited to aminic and phenolic antioxidants, commercial products are available from BASF under the tradenames Irganox® 1035, Irganox® L135, and Irganox® PS800FL.

In one embodiment, the protective coating composition comprises a non-reactive diluent. One example of a suitable non-reactive diluent is a polyalphaolefin (PAO), which may be an oligomer of an α-olefin. PAOs are generally high purity hydrocarbons with a paraffinic structure and a high degree of side chain branching, and the branching may include irregular branching or regular branching. The PAO may comprise oligomers or low molecular weight polymers of branched and/or linear alpha olefins. Suitable olefins include, but are not limited to, 1-butene, 1-pentene, 1-hexene, 1-heptene, 1-octene, 1-nonene, 1-decene, 1-undecene, 1-dodecene, 1-tridecene, 1-tetradecene, 1-pentadecene, 1-hexadecene, and blends thereof. Useful PAOs include certain grades of Synfluid® available from Chevron Phillips Chemical Company, including, for example, Synfluid® PAO 8.

In one embodiment, the substrate to be coated by the composition described herein is an electrical circuit assembly, including a base support with a plurality of electrical circuit components extending outwardly from the surface of the base support attached thereto and electrically connected to the electrical circuitry. The substrate is coated with a thin layer of the coating composition as defined and described in detail herein and the coating composition expands to form a closed cell foam coating.

In one embodiment, the base support comprises a printed circuit board assembly that includes a supporting base or a substrate upon which a conductive pattern of highly conductive material is attached to define interconnecting circuit conductors. Various electrical components such as resistors, transistors, and the like are mounted to the board and connected to the conductors. The components may also have terminals which may pass through board openings with electrical soldered connections. The soldered connections as well as the terminals define sharp projections or asperities which extend outwardly of the board and components.

The coating composition of the present invention may be prepared by mixing together all of the ingredients of Part A and then mixing Part A with Part B. As those skilled in the art will appreciate Part A and Part B can be combined or mixed in any manner acceptable to form such polymeric resin systems. Such methods include, but are not limited to, hand mixing, static mixing, dynamic mixing, or impingement mixing. It is further noted that the individual parts of the multi-part system can be added in any order (e.g., Part A can be mixed with Part B, or vice versa).

In one embodiment, it is preferred that Part A be mixed with Part B at the time the coating composition is brought into contact with the surface of the substrate or just prior to that time. In other words, once Part A is mixed with Part B the coating composition should be applied to or otherwise be brought into contact with the surface to be coated in less than 120 seconds, preferably less than 90 second, more preferably less than 60 seconds, more preferably less than 45 seconds, more preferably less than 30 seconds, most preferably less than 20 seconds. In one embodiment, Part A and Part B are mixed using a static mixer and applied to the surface of the substrate. In another embodiment, Part A and Part B are sprayed together to produce the desired mixing.

In addition, as described herein, the coating composition may be optimized to enhance its suitability for a particular coating method. For example, in one embodiment, the coating composition may be optimized for spray coating. In another embodiment, the coating composition may be optimized for coating the substrate by dispensing. The tables below provide examples of suitable Part A formulations for the two-part composition of the invention that may be mixed with a suitable Part B as further demonstrated in the Examples.

Exemplary Part A formulations of the two-part compositions that are optimized for spray coating include the following:

| Ingredient | Function | Concentration (wt. %) | |
|---|---|---|---|
| Emerox 14804 | Ethylene glycol dimerate | 92-95 | wt. % |
| | polyol 2.2 Fn | | |
| Water | Blow agent | 4-6 | wt. % |
| NIAX A1 | High efficiency blow catalyst | 0.25-1.0 | wt. % |
| NIAX A33 | Gel catalyst | 0.25-1.0 | wt. % |

Exemplary Part A formulations of the two-part compositions that are optimized for dispensing include the following:

| Ingredient | Function | Concentration (wt. %) | |
|---|---|---|---|
| Capa 3050 | Ester functional triol | 97-98.5 | wt. % |
| Water | Blow agent | 0.5-1.5 | wt. % |
| NIAX L6900 | Foam stabilizer | 0.25-1.5 | wt. % |
| NIAX EF600 | Low emission gel catalyst | 0.02-0.40 | wt. % |
| NIAX EF700 | Low emission blow catalyst | 0.02-0.30 | wt. % |
| | Density = 0.2-0.4 g/cm³ | | |

¹Capa products are available from Ingevity
²NIAX products are available from Momentive Performance Materials Inc.

It was observed that unlike with formulations that were optimized for spray coating, in compositions optimized for dispensing, the density (amount×expansion) appeared to be influenced by the concentration of the blowing agent, not the catalyst.

The thickness of the coating composition as applied is controlled so that the volume expansion is within the desired level. The coating generally expands preferentially in the Z direction due to the production of carbon dioxide. That is, in one embodiment, the volume expansion in the Z direction (i.e., in a vertical direction from the surface of the substrate) is controlled to be less than 25×, preferably between 8× and 20×, more preferably about 10× to about 15×. For example, in one embodiment, the coating is applied at a thickness of about 300 microns, which results in a 10× volume expansion. On the other hand, thicker coatings may result in a volume expansion of 25× or more, which might produce a less desirable result. Based thereon, the coating is applied as a liquid in a thickness that will produce the desired thickness of the expanded closed-cell foam protective coating.

In one embodiment, the coating composition is optimized so that the foaming reaction takes place in a time period of less than 10 minutes, preferably less than 5 minutes, more preferably less than 4 minutes at room temperature until the foamed coating is tack free. In one embodiment, the foaming reaction begins within 5 to 30 seconds of application.

In another embodiment, the composition is formulated to delay the onset of foaming and ease the application process. For example, in one embodiment, the foam catalyst may be microencapsulated in a water-soluble shell and incorporated in Part B. The water-soluble shell may take 5-10 minutes to dissolve and release the foam catalyst (which may be controlled by cell-wall thickness and solubility), resulting in the onset of foaming and polymerization. In another embodiment, the composition may be formulated to delay the onset of foaming by optimizing by varying the catalyst and concentrations of the catalyst and/or other ingredients to control the initiation speed of foaming and thus delay the onset.

In one embodiment, delayed foam development using a composition as described herein is achieved by using a low viscosity and slower gel to enable better flow around components.

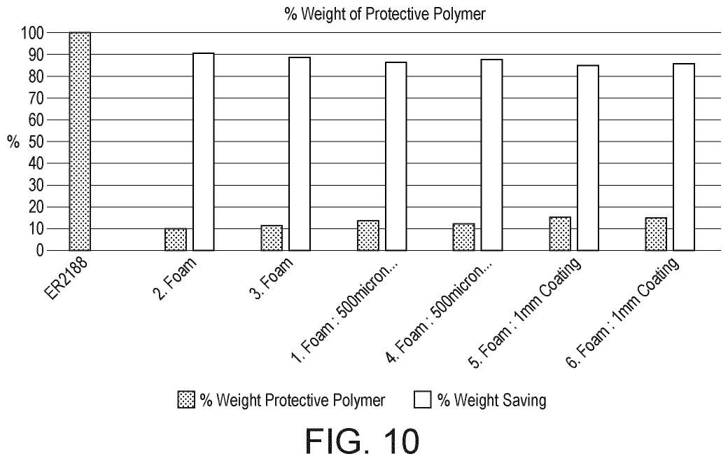

As illustrated in FIG. 10, a greater than 85% weight savings is achieved by using an expanded foam coating composition overcoated with a protective top cat layer as compared with a solid epoxy compound. In addition, it can be seen that the weight contributed by the thin top coat is negligible. Further, the application of the expanded foam layer does not slow down production time because the expanded foam coating layer is tack free in less than 5 minutes and can be over coated after about 2 minutes or after about 2.5 minutes or after about 3 minutes.

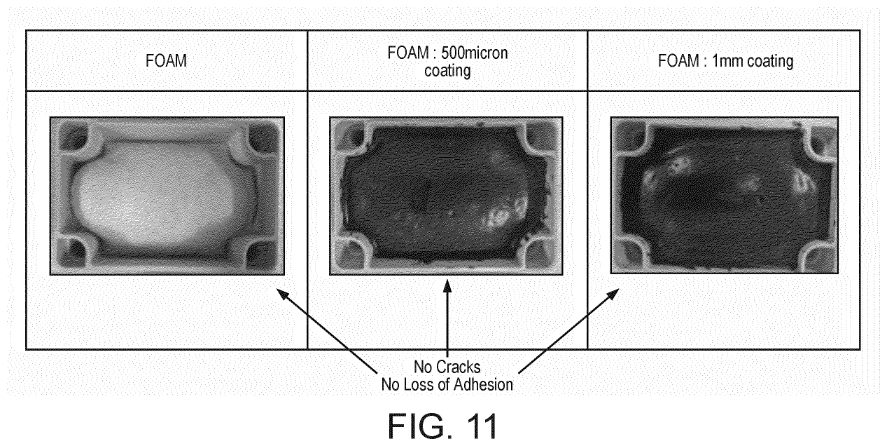

FIG. 11 illustrates an electronic component comprising a cavity that is filled with a foam composition as set forth in the instant invention as compared with a cavity that is filled with a foam composition and then overcoated with a thin (i.e., 500 micron or 1 mm protective coating). All three materials was subjected to thermal shock tests from −40° C. to +85° C., for 1000 cycles and all of the materials passes the thermal shock tests with no cracks or loss of adhesion.

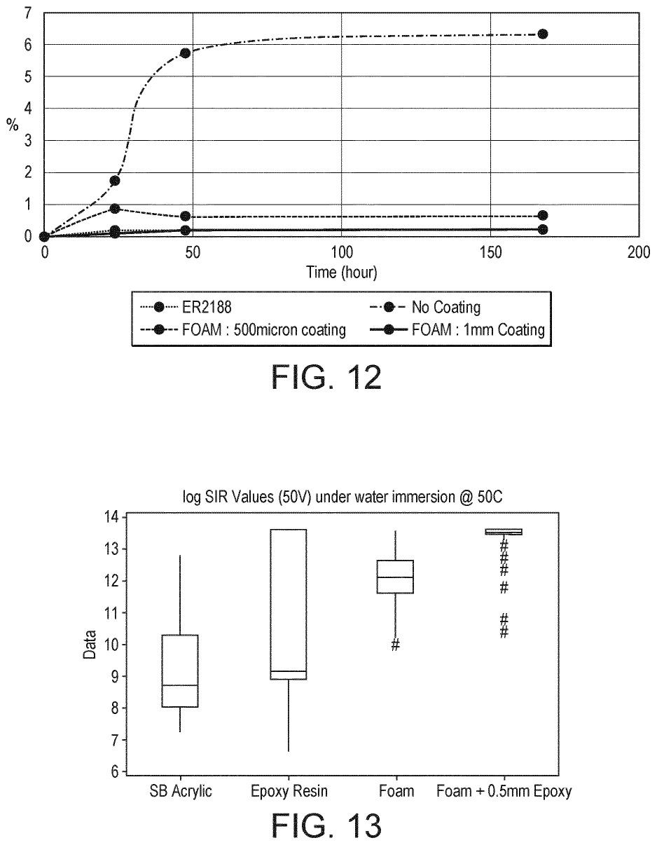

FIG. 12 depicts a graph that show the water-uptake improvement achieved by overcoating. As set forth in FIG. 12, a coating of expanded foam with no coating appeared to reach a saturation level at about 6.5%. In contrast, a coating of expanded foam with an overcoat layer exhibited improved saturation levels and the presence of a 1 mm top coat over an expanded foam layer yielded the same level of water-intake as a solid epoxy potting compound (i.e., ER2188).

Furthermore, FIG. 13 illustrates electrical insulation (50V) under immersion at 50° C. for 1 week. As seen in FIG. 13, water uptake does not lead to bad surface insulation resistance (SIR) in the expanded foam. In addition, it was determined that an expanded foam in combination with a 0.5 mm topcoat layer provided exemplary SIR and low water-uptake.

In one embodiment, the coating composition is optimized to facilitate application on complex circuit board designs. However, there is a tradeoff between cream time/rise time/tack free time and the volume height expansion.

In one embodiment, the expandable coating composition is formulated for latent foaming. In this instance, the coating composition is formulated to remain in an unexpanded state until foaming is initiated by an external force such as UV light, microwave, heat, or other external initiation source. As discussed above, in one embodiment, the expandable coating composition may be formulated for delayed onset of foaming and the time to foaming may be optimized to be at least about 3 minutes, or at least about 5 minutes or at least about 8 minutes.

In one embodiment, the coating composition can be constrained to produce an aesthetically pleasing housing with an entirely closed surface. For example, the foam may be constrained by placing a board in the housing so as to limit the expansion space of the foam. That is, in some embodiments, there is a benefit to constraining the foam during expansion to tailor the nature of the foam surface. In one embodiment, the coating described herein can be constrained, for example if the electronic substrate is placed in its housing. In this instance, the foamable coating can only expand within the confines of the housing. Otherwise, the coating is free to expand naturally until the foaming reaction is complete. In one embodiment, the coating may expand preferentially in the Z-direction due to carbon dioxide being produced.

The protective foam coating described herein preferably provides at least 100 MOhm insulation resistance at 85C/85% RH (insulation at combined high temperature and high humidity). In addition, the protective foam coating is also formulated to withstand at least 1000 thermal shock cycles from −40 to +130° C.

The volume and surface resistivity of the protective foam coating is preferably at least about 10¹¹ Ohm-cm (Vol) or Ohms per square (surface). If the value is below this level, the product will not exhibit adequate protective performance.

The water uptake of the protective closed-cell foam coating is preferably as low as possible. In one embodiment, the water uptake has a value performs comparably to typical resin systems, exhibiting less than 1% w/w water uptake after 14 days immersion.

The protective closed-cell foam coating preferably exhibits a % elongation at break of at least 10%, preferably in the range of 10 to 100%, more preferably 20 to 80%, most preferably about 40-60%.

In one embodiment, a top coat can be applied to the foamed coating, which top coat can be aesthetic or functional in nature and can modify the properties of the foamed coating. For example, a hard, chemically resistant coating can be applied on top of the foamed coating to provide abrasion and chemical resistance. Alternatively, an electrically conductive coating can be applied to provide RF shielding functionality. In this instance, the foam would act as the electrically insulating layer to prevent short-circuiting componentry of the circuit board or other electronic substrate. In still another embodiment, the foamed coating can be overcoated with a thin layer of an encapsulating resin. That is, once the foamed coating is formed on the surface of the electronic substrate, a thin layer of an encapsulating resin may be applied. The thin layer of the encapsulating resin may have a thickness of greater than 0 and less than 5 mm, preferably less than 4 mm, more preferably less than 3 mm, more preferably less than 2 mm, more preferably less than 1 mm, more preferably less than 0.5 mm.

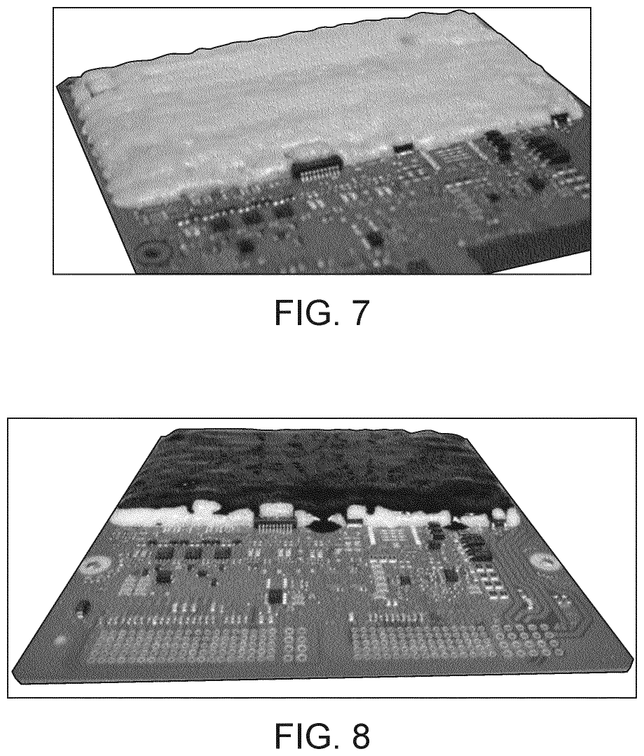

FIG. 7 depicts a view of an electronic assembly that has been partially coated with the protective coating of the invention. The coating of the present invention may also include a top coat applied over the expanded protective coating as shown in FIG. 8.

This top coat material may be added to improve abrasion resistance, solvent resistance, and/or electrical conductivity to act as a faraday cage for RF shielding. It is believed that the use of the protective coating described herein in combination with a top coat that provides improved electrical conductivity could replace or significantly strengthen the electronics housing.

In one embodiment, the top coat comprises a hard, chemical resistant coating that can provide abrasion and chemical resistance. In another embodiment, the top coat comprises an electrically conductive coating that can provide RF shielding functionality with the foam acting as the electrically insulating layer to prevent short-circuiting or altering the behavior of the electronic substrate (e.g., PCB).

In one embodiment, the top coat comprises a hydrophobic formulation that can also provide improved water-resistance. Many of these functions are typically handled by a metal or polymeric housing, which adds considerable weight. The use of the protective coating in combination with a topcoat layer can provide the same or similar level of protection as a metal or polymeric housing while substantially reducing the overall weight.

The ability to use a foamed coating in combination with a very thin layer of the encapsulating resin provides a weight savings of at least 75%, preferably at least 80%, more preferably at least 85% as compared with an electronic substrate that is coated with just an encapsulating resin.

The inventors of the present invention have found that the expanded protective coating described herein provides greater than about 90%, or 92% or even 94% weight saving as compared with the same volume of potting material or encapsulating resin. In addition, the expanded protective coating provides greater than about 10%, or 12% or even 14% weight saving as compared with a conformal coating and also provides more complete coverage. That is, the expanded protective coating of the present invention provides for complete coverage and/or encapsulating of feature, including vertical features, of the electronic substrate due to the vertical expansion of the material during foaming.

The present invention effectively solves problems of application speed, provides sufficient coverage of all of the feature contained on the electronic substrate and provides a coating layer that is able to provide protection against typical harsh environments.

The invention will now be described with respect to the following non-limiting examples.

### EXAMPLES

As set forth below, the expanded protective coatings were subjected to the following tests:

Condensation Tests were performed by the procedures developed by National Physical Laboratory (UK) using surface insulating resistance (SIR) measurements to predict circuit reliability.

Water vapor permeability tests were performed using a wet cup method (i.e., Payne Cup) in accordance with ASTM D1653.

Thermal shock was evaluated to measure resistance to failure from sudden extreme temperature changes (i.e., −40° C.→130° C.) over a short period of time.

Gravimetric water immersion tests were performed by a modified version of ASTM C272, testing the foams on a solder resist coated, epoxy laminate to simulate a circuit board construction.

Volume and surface resistivity of the expanded protective coating was performed in accordance with ASTM D-257.

Flame retardancy was evaluated by UL94 Vertical Burn test method, which is the Standard for Tests for Flammability of Plastic Materials for Parts in Devices and Appliances. Within this standard, materials are subjected to various burning tests to see their performance in flammable conditions. The UL 94 V flammability method evaluates both the burning and afterglow times after repeated flame application and dripping of the burning test specimen in a vertical burning test.

To attain an UL 94 V-0 standard, samples must have met the following criteria:
1) Burning combustion is not sustained for more than 10 seconds after applying controlled flame.
2) Total flaming combustion time for 5 samples does not exceed 50 seconds.
3) None of the samples burn up to the mounting clamp by either flaming or glowing combustion;
4) None of the samples drip flaming particles that result in the ignition of the surgical cotton below them; and
5) Samples do not exhibit glowing combustion for more than 30 seconds after removing the second controlled flame.

Tensile properties were evaluated in accordance with ASTM-D-638.

### Example 1

A composition was prepared as follows:

| | Component | Amount wt. % |
|---|---|---|
| Part A | | |
| Difunctional polyol | Emerox ® 14801 | 92.86 |
| Trifunctional polyol | | N/A |
| Foam Catalyst | NIAX A1 | 1.0 |
| | NIAX A33 | 1.0 |
| Gel Catalyst | Kosmos 16 | 0.14 |
| Water | DI water | 5 |
| Part B | | |
| MDI pre-polymer | Lupranat ® M20S | 100 |

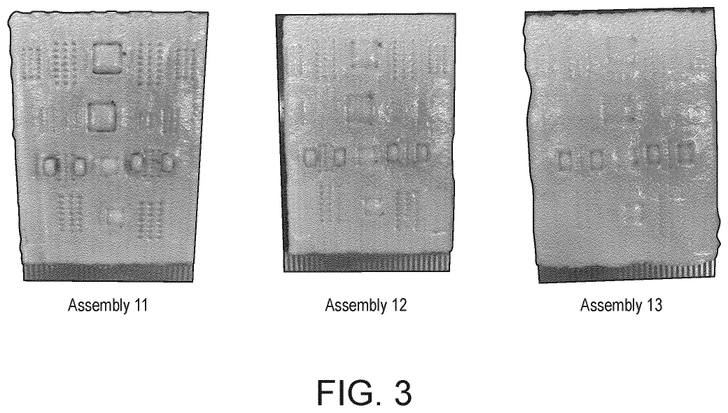

The ingredients of Part A were thoroughly mixed together and then the Part A was mixed with Part B at a ratio of 1.44:1 (w/w) prior to coating the composition onto a surface of an electronic substrate containing a number of vertical features at a thickness of 300 microns. The coating expanded by a factor of 10 within 4 minutes to a height of 3 mm to completely cover/encapsulate the vertical features as illustrated in FIG. 3.

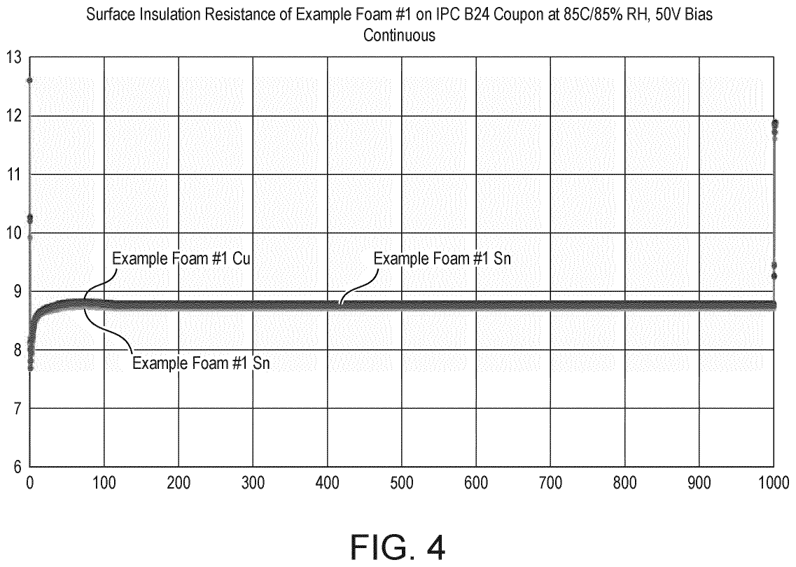

The material from Example 1 was applied to IPC B-24 test coupons (Immersion Tin and Bare Copper finish) at the same mix ratio (1.44:1 w/w), allowed to foam, harden and cure at RT for 24 hours, before being placed into a humidity chamber and ramped to 85° C./85% RH while the SIR was measured every 20 minutes at 50V bias. Of note, the Insulation Resistance of this foam remains above the common industry acceptance criteria of 100 MΩ (8 log Ω) throughout the 1000 hours of test. At the end of the test, the coating remains well adhered, and there are no signs of reversion or delamination, indicating the material is likely to provide excellent protection in high humidity conditions. The results are shown in FIG. 4.

### Example 2

A composition was prepared as follows:

| | Component | Amount wt. % |
|---|---|---|
| Part A | | |
| Difunctional polyol | Emerox 14801 | 46.43 |
| Trifunctional polyol | Castor oil | 46.43 |
| Foam Catalyst | NIAX A1 | 1.0 |
| | NIAX A33 | 1.0 |
| Gel Catalyst | Kosmos 16 | 0.14 |
| Water | DI water | 0.5% |
| Part B | | |
| MDI prepolymer | Isonate M143 | 100 |

The ingredients of Part A were thoroughly mixed together and then the Part A was mixed with Part B at a ratio of 1.04:1 (w/w) prior to coating the composition onto an automotive test board which was coated with 300 μm of liquid coating composition that expanded to 3 mm of cured expanded protective coating.

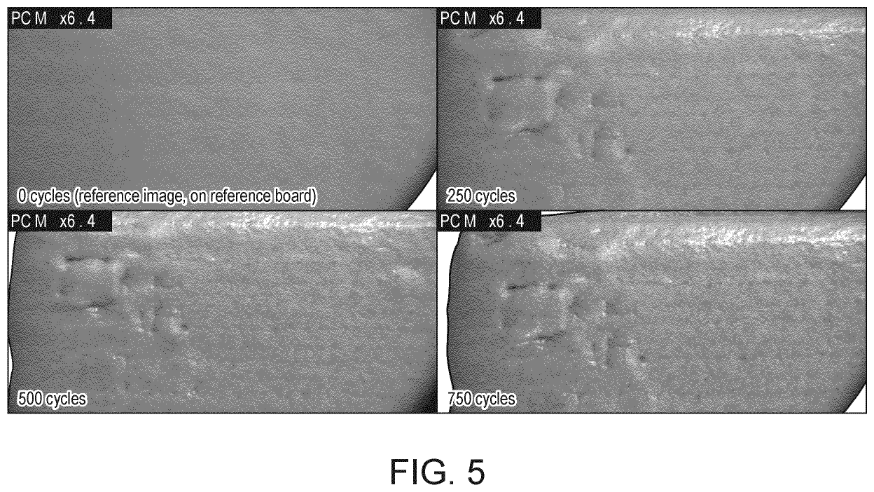

The coated assembly was then put through 1000 thermal shock cycles as described above and showed no evidence of cracking as shown in FIG. 5. While there were some signs of discoloration, there were no signs of cracking. There was also no noticeable embrittlement and the expanded protective coating remained soft and spongy.

It is also noted that colorants can be added to the composition as discussed above, if desired, to offset discoloration.

### Example 3

A composition was prepared as follows:

| | Component | Amount wt. % |
|---|---|---|
| Part A | | |
| Difunctional polyol | Krasol HLBH-1000 | 50.05 |
| Diol Chain extender | BEPD | 8.86 |
| Non-reactive diluent | Synfluid PAO 8 | 30 |
| Foam Catalyst | NIAX A1 | 1.2 |
| | NIAX A33 | 0.8 |
| Gel Catalyst | DBTDL (Dabco T12) | 0.09 |
| Water | DI water | 4.0 |
| Part B | | |
| MDI pre-polymer | Lupranat M20S | 100 |

The ingredients of Part A were thoroughly mixed. Part A was mixed with part B at a ratio of 1.6:1 (w/w) and coated onto a pre-weighed (4 dp) IPC B24 test board. After 24 hours, the coated board was weighed to 4 decimal places prior to being placed in DI water for 14 days. After 14 days, the coated assembly was removed, excess water was removed, and the “dry” assembly was immediately re-weighed to determine % water uptake of the coating as shown below.

| | Mass at t = 0 | Mass at t = 14 | Water uptake |
|---|---|---|---|
| Sample | grams | days grams | grams |
| Uncoated SIR board | 34.0859 | | |
| Board coated with | 38.1197 | 38.1569 | |
| Foam of Example 3 | | | |
| Weight of foam | 4.0338 | 4.0710 | 0.0372 |

The percentage of water uptake can be calculated as follows; 100*0.0372/4.0338=0.92%

### Example 4

A composition was prepared as follows:

| | Component | Amount wt. % |
|---|---|---|
| Part A | | |
| Difunctional polyol | Emerex 14801 | 36.43 |
| Trifunctional polyol | Castor oil | 36.43 |
| Flame retardant -- | FR Cros ® 489 | 20 |
| Encapsulated APP | | |
| Foam Catalyst | NIAX A1 | 1.0 |
| | NIAX A33 | 1.0 |
| Gel Catalyst | Kosmos 16 | 0.14 |
| Water | DI Water | 5 |
| Part B | | |
| MDI pre-polymer | Isonate M143 | 100 |

The ingredients of Part A were thoroughly mixed, and then Part A and Part B were mixed at a ratio of 1.32:1 (w/w) and approximately 0.5 ml was dispensed into a mold (13 mm×127 mm×3 mm) used to produce 3 mm thick samples which were subjected to UL94 V-0 Vertical Burn Testing. Samples were removed from the molds after 1 hour and then left overnight prior to performing the burn test. Flame samples were prepared in the same way from the analogous non-flame retarded coating of Example 2. The results are shown below.

| | Ave. T1 | Ave. T2 | | |
|---|---|---|---|---|
| | (sec.) | (sec.) | T1 + T2 | V rating |
| Example 2 | 25 | Burned to clamp | N/A | Fail |
| Example 4 | 5 | 2 | 7 | V-0 |

The non-flame retarded formulation of Example 2 burned completely, resulting in a UV94V fail, whereas the flame-retardant formulation of Example 4 met the UL94 V-0 criteria.

### Example 5

A composition was prepared as follows:

### Part A:

| Trade Name | Function | w/w % |
|---|---|---|
| Capa 3050¹ | Ester Functional Triol | 56 |
| Water | Blow Agent | 2.5 |
| NIAX L6900² | Foam Stabilizer | 1 |
| NIAX EF600² | Low Emission Gel Catalyst | 0.25 |
| NIAX EF700² | Low Emission Blow Catalyst | 0.25 |
| Graf Guard 210-200N | Flame Retardant | 40 |

¹Capa products are available from Ingevity
²NIAX products are available from Momentive Performance Materials Inc

Part B was a 50:50 blend of Ongronat 2100, a polymeric MDI with an average functionality of 2.6-2.7 (available from BorsodChem) and Desmodur E23, a solvent-free aromatic polyisocyanate prepolymer based on diphenylmethane diisocyanate.

The ingredients of Part A were thoroughly mixed, and then Part A and Part B were mixed at a ratio of 1.32:1 (w/w). Approximately 0.5 ml was dispensed into a mold used to produce 10 mm thick samples which were subjected to UL94 V-0 Vertical Burn Testing. As set forth above, 20% of expandable graphite was mixed into the polyol side of the two-part composition, resulting in an expanded protective coating that included 10.5 wt. % of the expandable graphite.

Samples were removed from the molds after 1 hour and then left overnight prior to performing the burn test. Flame samples were prepared in the same way from the analogous non-flame retarded coating of Example 2. The results are shown below.

### Specimen Thickness 10 mm

| Specimen | T1 | T2 | V− |
|---|---|---|---|
| 1 | 1 | 2 | 0 |
| 2 | 1 | 1 | 0 |
| 3 | 2 | 5 | 0 |
| 4 | 2 | 4 | 0 |
| 5 | 1 | 2 | 0 |

As seen from this table, all of the samples in accordance with this example passes the UV94 V-0 vertical flame test.

### Example 6

A composition was prepared as follows:

### Part A:

| Trade Name | Function | w/w % |
|---|---|---|
| Capa 3050¹ | Ester Functional Triol | 76 |
| Water | Blow Agent | 2.5 |
| NIAX L6900² | Foam Stabilizer | 1 |
| NIAX EF600² | Low Emission Gel Catalyst | 0.25 |
| NIAX EF700² | Low Emission Blow Catalyst | 0.25 |
| Graf Guard 210-200N | Flame Retardant | 20 |

¹Capa products are available from Ingevity
²NIAX products are available from Momentive Performance Materials Inc.

Part B was the same as in Example 5. The ingredients of Part A were thoroughly mixed, and then Part A and Part B were mixed at a ratio of 1.32:1 (w/w). Approximately 0.5 ml was dispensed into a mold used to produce 15 mm thick samples which were subjected to UL94V-0 Vertical Burn Testing. As set forth above, 40% of expandable graphite was mixed into the polyol side of the two-part composition, resulting in an expanded protective coating that included 23 wt. % of the expandable graphite.

Samples were removed from the molds after 1 hour and then left overnight prior to performing the burn test. Flame samples were prepared in the same way from the analogous non-flame retarded coating of Example 2. The results are shown below.

### Specimen Thickness 15 mm

| Specimen | T1 | T2 | V− |
|---|---|---|---|
| 1 | 5 | 2 | 0 |
| 2 | 1 | 3 | 0 |
| 3 | 2 | 2 | 0 |
| 4 | 5 | 1 | 0 |
| 5 | 2 | 4 | 0 |

### Comparative Example 1

A composition was prepared as follows:

| | Component | Amount wt. % |
|---|---|---|
| Part A | | |
| Difunctional polyol | Emerox 14801 | 46.11% |
| Trifunctional polyol | Lupranol 1000 | 46.25% |
| Foam Catalyst | NIAX A1 | 0.99% |
| | NIAX A33 | 1.04% |
| Gel Catalyst | Kosmos 16 | 0.60% |
| Water | DI Water | 5.01% |
| Part B | | |
| MDI pre-polymer | Lupranat ® M20S | 100 |

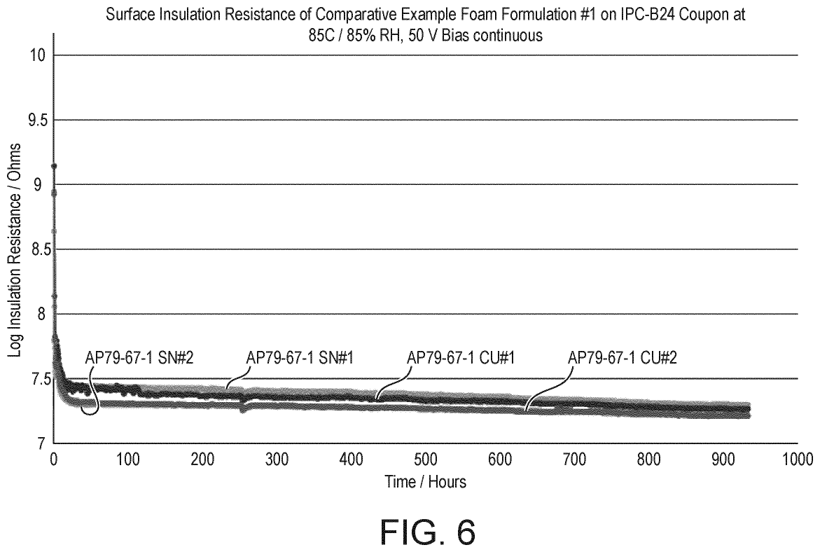

The ingredients of Part A were thoroughly mixed and then parts A and B were combined at a ratio of 1.90:1 (w/w) and dispensed onto IPC-B24 test coupons (both Immersion Tin and Bare Copper finish) and allowed to foam, harden and cure for 24 hours prior to being placed into a humidity chamber and ramped to 85° C./85% RH whilst the SIR was measured every 20 minutes at 50V bias, for a period of approximately 1000 hours. The recorded insulation resistance values are shown below. Of note, the insulation resistance quickly drops below the industry accepted value of 100 MΩ (8 log Ω), and continues to trend downwards, implying that the material is an inadequate moisture barrier and protective coating. Upon removal from the chamber, Comparative Example Foam #1 showed a significant reduction in volume, an area of delamination and signs of reversion in that the surface was tacky, compared with Foam Example #1 which was essentially unchanged after the 1000 hour exposure at 85° C./85% RH. The results are shown in FIG. 6.

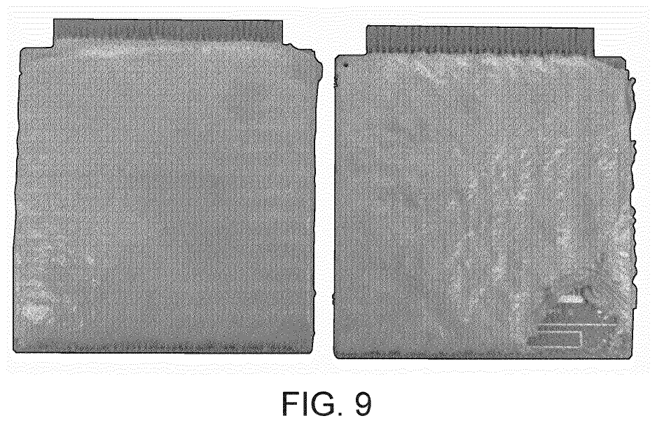

FIG. 9 depicts a comparison of an electronic assembly coated with the composition of Example 1 and an electronic assembly coated with the composition of Comparative Example 1 after 1000 hours at 85° C./85% RH. As seen in FIG. 9, the composition of Example 1 provides a coated that provides good protection of the electronic assembly while the coating produced in accordance with the composition of Comparative Example 1 deteriorated and provided an inadequate moisture barrier and protective coating.

Although the present disclosure has been described with reference to exemplary implementations, the present disclosure is not limited by or to such exemplary implementations. Rather, various modifications, refinements and/or alternative implementations may be adopted without departing from the spirit or scope of the present disclosure.

In addition, while the present invention has been described as providing an expanded protective coating on an electronic substrate, it is believed that there are other applications in which an expanded coating that is lightweight and strong and provides electrically insulating, thermally insulating and/or barrier properties would be beneficial and therefore electronic substrates are only one exemplary application of the protective coatings described herein, alone or in combination with a suitable top coat over the expanded coating layer.

1. A two-part coating composition for coating electronic components, wherein the two-part coating composition comprises:
a) Part A comprising:
a. a polyol component comprising at least one of a difunctional polyol, a trifunctional polyol, and a tetra functional polyol;
b. a foam catalyst;
c. optionally, a gel catalyst;
d. optionally, at least one flame retardant; and
e. water; and
b) Part B comprising:
a. an isocyanate prepolymer with a functionality of greater than 2 and less than 3, and
b. optionally, at least one flame retardant;
wherein the flame retardant must be present in at least one of Part A and Part B.

2. The two-part coating composition according to claim 1, wherein the difunctional polyol is present and is selected from the group consisting of polyethylene glycol, polypropylene glycol, polycaprolactone, polybutadiene, polyester, polyether, polyfamesene, ethylene glycol dimerates, and combinations of two or more of the foregoing.

3. (canceled)

4. The two-part coating composition according to claim 1, wherein the trifunctional polyol is present and is selected from the group consisting of polyethylene glycol, polypropylene glycol, polycaprolactone, polybutadiene, polyester, polyether, polyfamesene, ethylene glycol dimerates, castor oil, and combinations of two or more of the foregoing.

5. (canceled)

6. (canceled)

7. The two-part coating composition according to claim 1, wherein the polyol component comprises 30-70 wt. % of the difunctional polyol.

8. The two-part coating composition according to claim 7, wherein the polyol component comprises 45-55 wt. % of the difunctional polyol.

9. (canceled)

10. The two-part coating composition according to claim 1, wherein the polyol component comprises 30-70 wt. % of the trifunctional polyol.

11. The two-part coating composition according to claim 10, wherein the polyol component comprises 45-55 wt. % of the trifunctional polyol.

12. (canceled)

13. The two-part coating composition according to claim 1, wherein the polyol component comprises 30-70 wt. % of the tetra functional polyol.

14. The two-part coating composition according to claim 13, wherein the polyol component comprises 45-55 wt. % of the tetra functional polyol.

15. (canceled)

16. The two-part coating composition according to claim 1, wherein the water content of Part A is in a range of 0.05 to 10 wt. %.

17. (canceled)

18. (canceled)

19. (canceled)

20. (canceled)

21. The two-part coating composition according to claim 1, wherein the foam catalyst is an amine catalyst selected from the group consisting of fatty amines, alicyclic amines, aromatic amines, alcohol amines or one of their ammonium compounds, triethylenediamine, N,N,N,N-tetramethylalkylenediamine, N,N,N,N-pentamethyldiethylenetriamine, triethylamine, N,N-dimethylbenzylamine, N,N-dimethylhexadecylamine, N,N-dimethylbutylamine, N-ethylmorpholine, N-methylmorpholine, N,N-diethylpiperazine, N-diethyl-2-methyl piperazine, N,N-bis-(α-hydroxypropyl)-2-methylpiperazine, N-hydroxypropyldimethylmorpholine, pyridine, N,N-dimethylpyridine, and combinations of two or more of the foregoing.

22. (canceled)

23. (canceled)

24. The two-part coating composition according to claim 1, wherein the gel catalyst is an organo-metallic catalyst or an amine catalyst.

25. The two-part coating composition according to claim 24, wherein the organo-metallic catalyst is selected from the group consisting of dialkyl tin dialkanoates, stannous octoate, dibutyltin dilaurate, dibutyltin diacetate, a blend of zinc neodecanoate, bismuth neodecanoate and neodecanoic acid, ferric acetylacetonate, potassium acetate catalysts, potassium octoate catalysts, stannous octoate catalysts, bismuth based gelation catalysts, and combinations of the foregoing.

26. (canceled)

27. (canceled)

28. The two-part coating composition according to claim 1, wherein Part A further comprises a chain extender selected from the group consisting of aliphatic, araliphatic, aromatic and/or cycloaliphatic diol and diamine compounds.

29. (canceled)

30. The two-part coating composition according to claim 28, wherein the chain extender is selected from the group consisting of 1,2-ethylene diol, 1,4-butanediol, 1,6-hexanediol, 1,3-propanediol, and/or dialkylene-, trialkylene-, tetraalkylene-, pentaalkylene-, hexaalkylene-, heptaalkylene-, octaalkylene-, nonalkylene, and decaalkylene-glycols having from 2 to 8 carbon atoms in the alkylene moiety, corresponding oligopropyleneglycols and/or propylene glycols.

31. The two-part coating composition according to claim 1, wherein Part A further comprises an inert mineral filler or extender selected from the group consisting of talc, calcium carbonate, silica, wollastonite, aluminum hydroxide, kaolin, clays, calcium sulfate fibers, mica, glass beads, and nanomaterials selected from the group consisting of nano-graphene, nanofibers and nanoparticles.

32. (canceled)

33. The two-part coating composition according to claim 1, wherein the flame retardant is selected from the group consisting of aluminum hydroxide trihydrate, phosphorus containing polyol, micro-encapsulated ammonium poly phosphate, solid flame retardants, and combinations of the foregoing.

34. The two-part coating composition according to claim 33, wherein the flame retardant is a solid at room temperature, wherein the solid flame retardant has a typical average particle size of 50 to 500 microns.

35. (canceled)

36. (canceled)

37. The two-part coating composition according to claim 33, wherein the flame retardant is a solid flame retardant and comprises expandable graphite or a combination of aluminum hydroxide trihydrate and expandable graphite.

38. (canceled)

39. A method of applying a protective coating to one or more surfaces of an electronic substrate, the method comprising the steps of:
a) mixing a two-part coating composition comprising:
i. Part A comprising:
a. a polyol component comprising at least one of a difunctional polyol, a trifunctional polyol, and a tetra functional polyol;
b. a foam catalyst;
c. optionally, a gel catalyst;
d. optionally, at least one flame retardant; and
e. water; and
ii. Part B comprising:
a. an isocyanate prepolymer with a functionality of greater than 2 and less than 3, and
b. optionally, at least one flame retardant,
wherein the at least one flame retardant must be present in at least one of Part A and Part B, to prepare a liquid coating composition; and
b) applying the liquid coating composition to the electronic substrate and allowing the liquid coating composition to expand into a closed-cell foam coating.

40. The method according to claim 39, wherein the liquid coating composition expands in volume in a vertical direction from the surface of the electronic substrate by a factor of less than 25× of an applied thickness of the liquid coating composition to form the expanded closed-cell foam coating.

41. The method according to claim 40, wherein the liquid coating composition expands in volume in a vertical direction from the surface of the electronic substrate by a factor between 8× and 20× of an applied thickness of the liquid coating composition to form the expanded closed-cell foam coating.

42. (canceled)

43. The method according to claim 39, wherein the foam reaction takes place in less than 10 minutes to produce a tack-free coating.

44. The method according to claim 43, wherein the foam reaction takes place in less than 5 minutes to produce a tack-free coating.

45. (canceled)

46. The method according to claim 39, wherein the liquid coating composition is applied by spraying or dispensing.

47. (canceled)

48. The method according to claim 39, wherein the electronic substrate comprises at least one of asperities and protrusions and the expanded coating composition encloses the at least one of asperities and protrusions.

49. The method according to claim 39, further comprising the step of applying a topcoat layer over the expanded closed-cell foam coating, wherein the topcoat layer is selected from the group consisting of chemical resistant coatings, hydrophobic coatings, microencapsulation resins, and combinations of the foregoing.

50. The method according to claim 49, wherein the topcoat layer has a thickness of greater than 0 and less than 5 mm.

51. (canceled)

52. (canceled)

53. (canceled)

54. (canceled)

55. (canceled)

56. (canceled)

57. The method according to claim 39, wherein the expanded closed-cell foam coating is flame retardant and is capable of passing a UL94 V-0 vertical burn test.

58. The method according to claim 39, wherein the liquid coating composition is constrained in at least one direction to limit the expansion space of the closed-cell foam coating.

59. The method according to claim 39, wherein the liquid coating composition is formulated to delay the onset of foam by microencapsulating the foam catalyst or by controlling the initiation speed of foaming.

60. (canceled)

61. An electronic substrate assembly comprising a printed circuit board, wherein the printed circuit board comprises a base support and a plurality of electrical circuit components extending outwardly from the surface of the base support attached thereto and electrically connected to the electrical circuitry, and wherein a closed-cell foam protective coating is applied to at least a portion of the surface of the electronic substrate assembly comprising the plurality of electrical circuit components, wherein the closed-cell foam protective coating is applied by the method of claim 39.

62. The electronic substrate assembly according to claim 61, wherein the closed-cell foam protective coating is capable of passing a UL94 V-0 vertical burn test.

63. The electronic substrate assembly according to claim 61, further comprising a topcoat layer over the closed cell foam protective coating, wherein the topcoat layer is selected from the group consisting of chemical resistant coatings, hydrophobic coatings, microencapsulation resins, and combinations of the foregoing.

64. The electronic substrate assembly according to claim 63, wherein the topcoat layer has a thickness of greater than 0 and less than 5 mm.

65. (canceled)

66. (canceled)

67. (canceled)

68. (canceled)

69. (canceled)

70. (canceled)

71. The two-part coating composition according to claim 1, wherein the polyol component comprises 30-70 wt. % of the difunctional polyol and 30-70 wt. % of the trifunctional polyol.

72. The method according to claim 39, wherein the overcoated closed-cell foam coating exhibits less than 1% w/w water uptake after 14 days of immersion.

73. The method according to claim 39, wherein the overcoated closed-cell foam coating exhibits no cracks or loss of adhesion after being subjected to thermal shock from −40° C. to 85° C. for 1000 cycles.

74. A method of using a two-part coating composition to repair or modify an electronic substrate having one or more features thereon, the method comprising the steps of:
a) removing an encapsulating material from the electronic substrate to reveal one or more features thereon;
b) applying a two-part coating composition to the surface of the electronic substrate having the one or more features thereon, the two-part coating composition comprising:
i) Part A comprising:
a. a polyol component comprising at least one of a difunctional polyol, a trifunctional polyol, and a tetra functional polyol;
b. a foam catalyst;
c. optionally, a gel catalyst;
d. optionally, at least one flame retardant; and
e. water; and
ii) Part B comprising:
a. an isocyanate prepolymer with a functionality of greater than 2 and less than 3, and
b. optionally, at least one flame retardant,
wherein the at least one flame retardant must be present in at least one of Part A and Part B, to prepare a liquid coating composition; and
c) allowing the two-part coating composition to expand into a closed-cell foam coating; and
d) optionally, applying a topcoat layer over the expanded closed-cell foam coating, wherein the topcoat layer is selected from the group consisting of chemical resistant coatings, hydrophobic coatings, microencapsulation resins, and combinations of the foregoing.
